(19) United States
(12) Patent Application Publication
(10) Pub. No.: US 2025/0022924 A1
(43) Pub. Date: Jan. 16, 2025

(54) SEMICONDUCTOR DEVICE

(71) Applicant: Renesas Electronics Corporation, Tokyo (JP)

(72) Inventor: Keiichi MAEKAWA, Tokyo (JP)

(21) Appl. No.: 18/766,799

(22) Filed: Jul. 9, 2024

(30) Foreign Application Priority Data
Jul. 11, 2023 (JP) 2023-113605

(51) Int. Cl. H01L 29/40; H01L 29/423

(52) U.S. Cl. CPC H01L 29/407; H01L 29/42336; H01L 29/4236

(57) ABSTRACT

A field plate electrode FP and a gate electrode GE are formed inside a plurality of trenches TR1. An outer peripheral trench TR2 surrounds the plurality of trenches TR1 in plan view. A field plate electrode FP (lead-out portion FPa) is formed inside the outer peripheral trench TR2. The outer peripheral trench TR2 has an extending part TR2a extending in the Y direction, an extending part TR2b extending in the X direction, and a corner part TR2c extending in a direction different from the X and Y directions in plan view and connecting the extending part TR2a and the extending part TR2b. In the Y-direction, the distance L2 between the end part 10 of the closest trench TR1 closest to the extending part TR2a and the extending part TR2b is longer than the distance L3 between the end part 10 of the other trench TR1 and the extending part TR2b.

### CROSS-REFERENCE TO RELATED APPLICATIONS

The disclosure of Japanese Patent Application No. 2023-113605 filed on Jul. 11, 2023, including the specification, drawings and abstract is incorporated herein by reference in its entirety.

### BACKGROUND

The present disclosure relates to a semiconductor device, and more particularly, to a semiconductor device including a gate electrode and a field plate electrode inside a trench.

In a semiconductor device including a semiconductor element such as a power MOSFET (Metal Oxide Semiconductor Field Effect Transistor), a trench gate structure in which a gate electrode is embedded in a trench is applied. As a type of trench gate structure, a split gate structure has been developed in which a field plate electrode is formed at a lower part of a trench and a gate electrode is formed at an upper part of the trench. A source potential is supplied from the source electrode to the field plate electrode. By expanding the depletion layer in the drift region by the field plate electrode, it is possible to increase the concentration of the drift region, and it is possible to reduce the resistance of the drift region.

Further, the outer periphery of a semiconductor device is structured to improve the withstand voltage. For example, in Patent Document 1, an outer peripheral trench is formed so as to surround a cell region in which a plurality of MOSFET are formed. A field plate electrode is also formed inside the outer peripheral trench.

There is a disclosed technique listed below.
[Patent Document 1] Japanese Unexamined Patent Application Publication No. 2021-82770

### SUMMARY

The outer peripheral trench extends in the X direction and the Y direction in plan view so as to surround the cell region. However, in a corner part where the outer peripheral trench in the X direction and the outer peripheral trench in the Y direction intersect with each other, the depletion layer extending from both the X direction and the Y direction and the depletion layer extending from the end part of the trench in the cell region tend to locally overlap with each other as compared to the planar part of the outer peripheral trench independent in the X direction and the Y direction, respectively. Therefore, the charge balance is biased, and a phenomenon such as partial depletion or electric field concentration is likely to occur. That is, there is a problem that the breakdown voltage is likely to decrease in the vicinity of the corner part.

A main purpose of the present application is to increase the breakdown voltage around the outer peripheral trench by reducing the overlap of the depletion layer around the corner part where the outer peripheral trench in the X direction and the outer peripheral trench in the Y direction intersect, thereby stabilizing the breakdown voltage of the semiconductor device.

Other objects and novel features will become apparent from the description of this specification and the accompanying drawings.

The typical ones of the embodiments disclosed in the present application will be briefly described as follows.

A semiconductor device according to one embodiment comprises: a semiconductor substrate of a first conductivity type having an upper surface and a lower surface; a plurality of trenches being formed in the semiconductor substrate so as to reach a predetermined depth from the upper surface of the semiconductor substrate to the lower surface of the semiconductor substrate, the plurality of trenches extending in a first direction in plan view and adjacent to each other in a second direction orthogonal to the first direction in plan view; a plurality of first field plate electrodes formed inside the plurality of trenches, respectively, and electrically insulated from the semiconductor substrate; a plurality of first gate electrodes formed above the plurality of first field plate electrodes, respectively, and electrically insulated from the semiconductor substrate and the plurality of first field plate electrodes, respectively; an outer peripheral trench formed in the semiconductor substrate so as to reach a predetermined depth from the upper surface of the semiconductor substrate toward the lower surface of the semiconductor substrate, the outer peripheral trench extending in the first direction and the second direction so as to surround the plurality of trenches in plan view; and a second field plate electrode formed inside the outer peripheral trench and electrically insulated from the semiconductor substrate. The outer peripheral trench comprises: a first extending part extending in the first direction; a second extending part extending in the second direction; and a corner part extending in a direction different from the first and second directions in plan view and interconnecting the first extending part and the second extending part. The plurality of trenches comprises: a first trench closest to the first extending part in the second direction; and a second trench next closest to the first extending part after the first trench in the second direction. The first trench has a first end part located near the second extending part in the first direction. The second trench has a second end part located near the second extending part in the first direction. A distance between the first end part and the second extending part is longer than a distance between the second end part and the second extending part in the first direction.

A semiconductor device according to one embodiment comprises: a semiconductor substrate of a first conductivity type having an upper surface and a lower surface; a plurality of trenches being formed in the semiconductor substrate so as to reach a predetermined depth from the upper surface of the semiconductor substrate to the lower surface of the semiconductor substrate, the plurality of trenches extending in a first direction in plan view and adjacent to each other in a second direction orthogonal to the first direction in plan view; a plurality of first field plate electrodes formed inside the plurality of trenches, respectively, and electrically insulated from the semiconductor substrate; a plurality of first gate electrodes formed above the plurality of first field plate electrodes, respectively, and electrically insulated from the semiconductor substrate and the plurality of first field plate electrodes, respectively; an outer peripheral trench formed in the semiconductor substrate so as to reach a predetermined depth from the upper surface of the semiconductor substrate toward the lower surface of the semiconductor substrate, the outer peripheral trench extending in the first direction and the second direction so as to surround the plurality of trenches in plan view; and a second field plate electrode formed inside the outer peripheral trench and electrically insulated from the semiconductor substrate. The outer peripheral trench comprises: a first extending part extending in the first direction; a second extending part extending in the second direction; and a corner part extending in a direction different from the first and second directions in plan view and interconnecting the first extending part and the second extending part. The plurality of trenches comprises: a first trench closest to the first extending part in the second direction; and a second trench next closest to the first extending part after the first trench in the second direction. The first trench has a first end part located near the second extending part in the first direction. The second trench has a second end part located near the second extending part in the first direction. The shape of the first end part is different from the shape of the second end part.

The semiconductor device according to one embodiment comprises: a semiconductor substrate of a first conductivity type having an upper surface and a lower surface; a plurality of trenches being formed in the semiconductor substrate so as to reach a predetermined depth from the upper surface of the semiconductor substrate to the lower surface of the semiconductor substrate, the plurality of trenches extending in a first direction in plan view and adjacent to each other in a second direction orthogonal to the first direction in plan view; a plurality of first field plate electrodes formed inside the plurality of trenches, respectively, and electrically insulated from the semiconductor substrate; a plurality of first gate electrodes formed above the plurality of first field plate electrodes, respectively, and electrically insulated from the semiconductor substrate and the plurality of first field plate electrodes, respectively; an outer peripheral trench formed in the semiconductor substrate so as to reach a predetermined depth from the upper surface of the semiconductor substrate toward the lower surface of the semiconductor substrate, the outer peripheral trench extending in the first direction and the second direction so as to surround the plurality of trenches in plan view; a second field plate electrode formed inside the outer peripheral trench and electrically insulated from the semiconductor substrate; and a first impurity region formed in the semiconductor substrate located between the plurality of trenches and the outer peripheral trench and having a second conductivity type opposite to the first conductivity type. The outer peripheral trench comprises: a first extending part extending in the first direction; a second extending part extending in the second direction; and a corner part extending in a direction different from the first and second directions in plan view and interconnecting the first extending part and the second extending part. The plurality of trenches comprises a first trench closest to the first extending part in the second direction. A second impurity region is formed in the semiconductor substrate located between the corner part and the first trench. An impurity concentration of the second impurity region is higher than an impurity concentration of the first impurity region.

According to one embodiment, the breakdown voltage of semiconductor device can be stabilized.

### BRIEF DESCRIPTION OF THE DRAWINGS

FIG. 1 is a plan view indicating a semiconductor device in a first embodiment.

FIG. 2 is a main part plan view indicating the semiconductor device in the first embodiment.

FIG. 3 is a main part plan view indicating the semiconductor device in the first embodiment.

FIG. 4 is a cross-sectional view indicating the semiconductor device in the first embodiment.

FIG. 5 is a main part plan view showing the periphery of the corner part of the outer peripheral trench in the first embodiment.

FIG. 6 is a main part plan view showing a depletion layer extending around the corner part of the outer peripheral trench in the first embodiment.

FIG. 7 is a graph showing the measurement result by the present inventor.

FIG. 8 is a cross-sectional view showing the manufacturing process of the semiconductor device in the first embodiment.

FIG. 9 is a cross-sectional view illustrating a manufacturing step following FIG. 8.

FIG. 10 is a cross-sectional view illustrating a manufacturing process following FIG. 9.

FIG. 11 is a cross-sectional view illustrating a manufacturing step following FIG. 10.

FIG. 12 is a cross-sectional view illustrating a manufacturing process following FIG. 11.

FIG. 13 is a cross-sectional view illustrating a manufacturing process following FIG. 12.

FIG. 14 is a cross-sectional view illustrating a manufacturing process following FIG. 13.

FIG. 15 is a cross-sectional view illustrating a manufacturing process following FIG. 14.

FIG. 16 is a cross-sectional view illustrating a manufacturing step following FIG. 15.

FIG. 17 is a main part plan view showing the periphery of the corner part of the outer peripheral trench in a second embodiment.

FIG. 18 is a main part plan view showing a depletion layer extending around the corner part of the outer peripheral trench in the second embodiment.

FIG. 19 is a main part plan view showing the periphery of the corner part of the outer peripheral trench in a third embodiment.

FIG. 20 is a main part plan view showing a depletion layer extending around the corner part of the outer peripheral trench in the third embodiment.

FIG. 21 is a cross-sectional view indicating the semiconductor device in the third embodiment.

FIG. 22 is a main part plan view showing the periphery of the corner part of the outer peripheral trench in a fourth embodiment.

FIG. 23 is a main part plan view showing a depletion layer extending around the corner part of the outer peripheral trench in the fourth embodiment.

FIG. 24 is a main part plan view showing the periphery of the corner part of the outer peripheral trench in an examined example.

FIG. 25 is a main part plan view showing a depletion layer extending around the corner part of the outer peripheral trench in an examined example.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, the X direction, the Y direction, and the Z direction described in the present application intersect each other and are orthogonal to each other. In the present application, the Z direction is described as a vertical direction, a height direction, or a thickness direction of a certain structure. In addition, the expression “plan view” used in the present application means that the plane formed by the X direction and the Y direction is a “plane” and the “plane” is viewed from the Z direction.

### First Embodiment

### <Structure of Semiconductor Device>

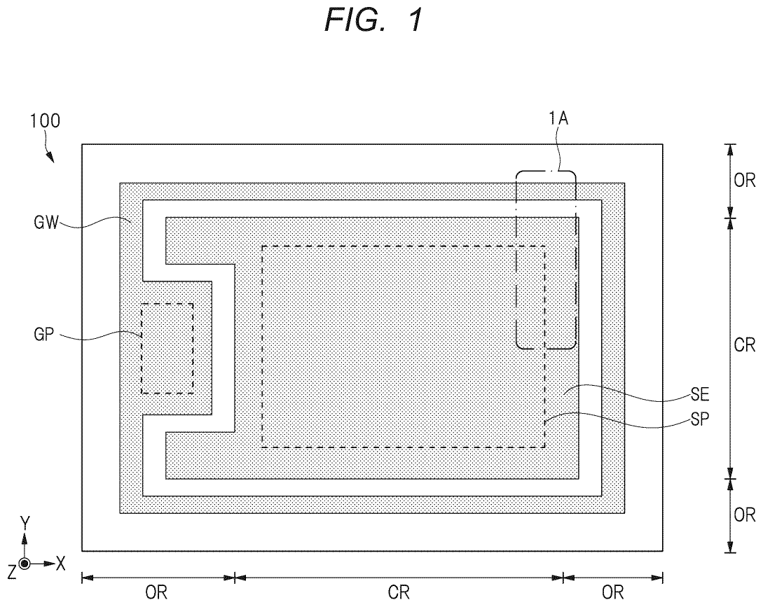

A semiconductor device 100 in the first embodiment will be described below with reference to FIGS. 1 to 7. The semiconductor device 100 includes a trench gate-structured MOSFET as a semiconducting element. The MOSFET of the first embodiment has a split gate structure including a gate electrode GE and a field plate electrode FP inside the trench TR1.

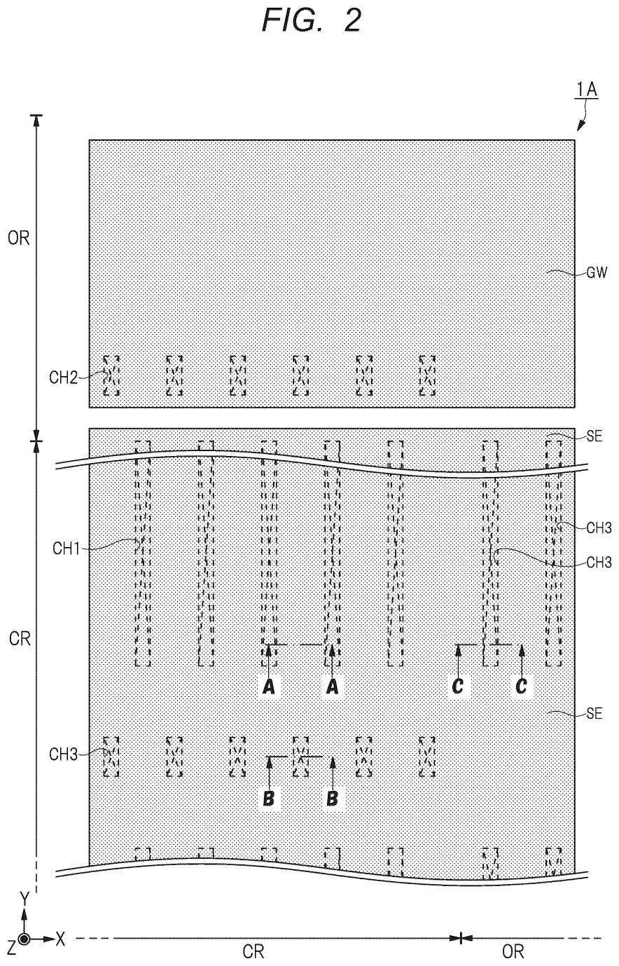

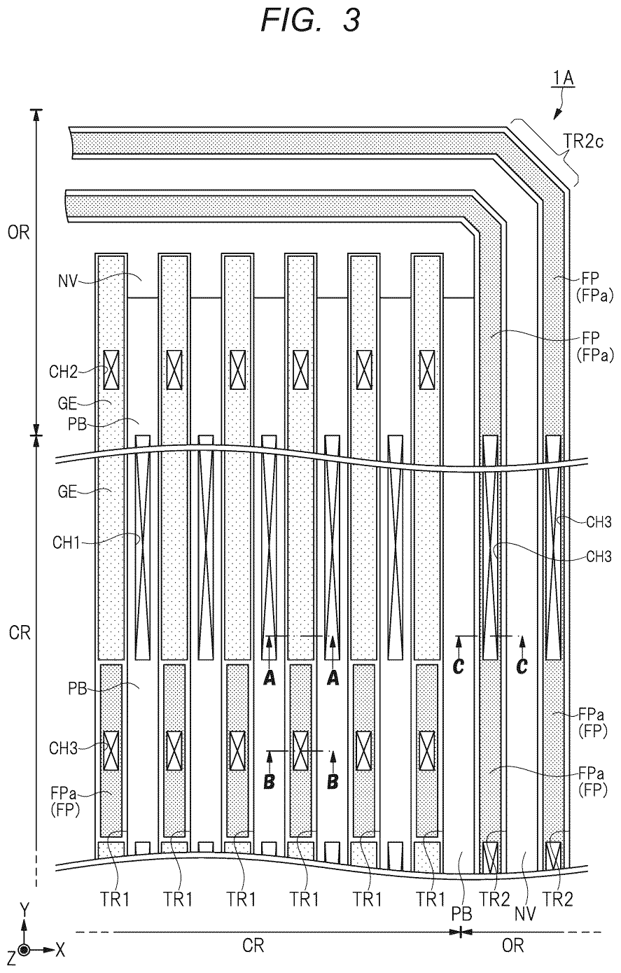

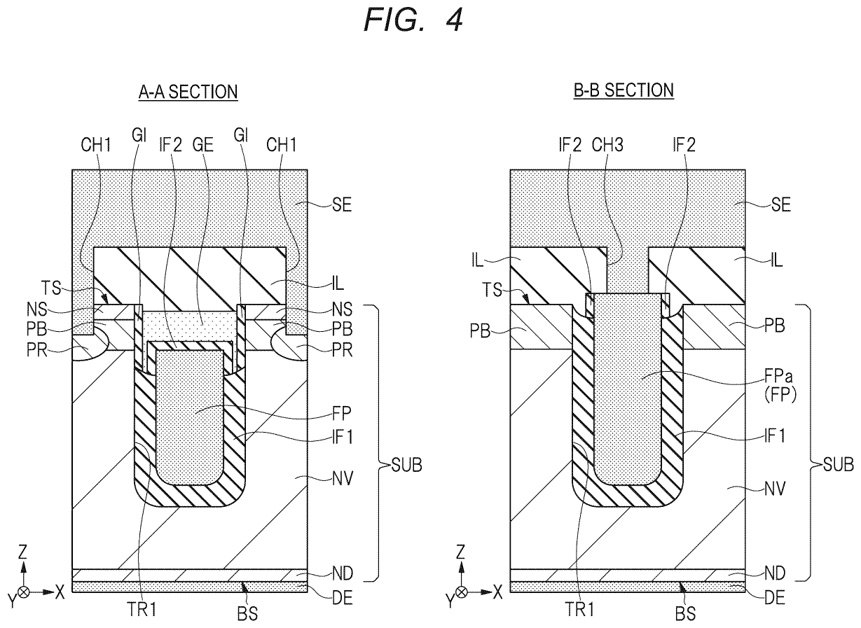

FIG. 1 is a plan view of a semiconductor chip as the semiconductor device 100. FIG. 2 and FIG. 3 are enlarged main part plan views of the region 1A shown in FIG. 1. FIG. 3 shows the structure under FIG. 2, mainly showing the trench gate structure formed in the semiconductor substrate SUB. In addition, the positions of the holes CH1, CH2, CH3 indicated by the dashed lines in FIG. 2 coincide with the positions of the holes CH1, CH2, CH3 shown in FIG. 3. FIG. 4 is a cross-sectional view along A-A and B-B lines shown in FIGS. 2 and 3.

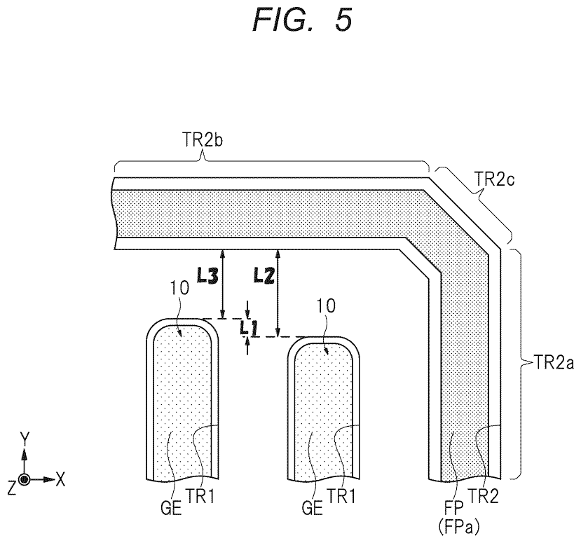

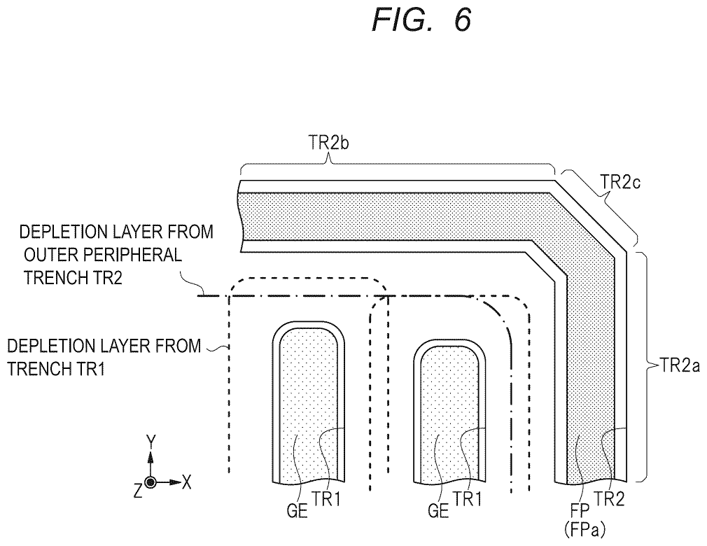

FIG. 5 and FIG. 6 show an enlarged periphery of the corner part TR2c of the outer peripheral trench TR2 shown in FIG. 3. While the main features of the present application are in the construction around the corner part TR2c, such features are detailed below.

FIG. 1 shows a wiring patterning formed primarily above the semiconductor substrate SUB. The semiconductor device 100 has a cell region CR and an outer peripheral region OR surrounding the cell region CR in plan view. In the cell region CR, main semiconductor elements such as a plurality of MOSFET are formed. The outer peripheral region OR is used to connect the gate wiring GW to the gate electrode GE, to form an outer peripheral trench TR2 that functions as a termination region, and the like. As shown in FIGS. 1 and 2, most of the cell region CR is covered with a source electrode SE. In plan view, the gate wiring GW surrounds the source electrode SE in plan view. Although not illustrated here, the source-electrode SE and the gate wiring GW are covered with a protective film such as a polyimide film. Openings are provided in parts of the protective film, and the source electrode SE and the gate wiring GW exposed in the openings become the source pad SP and the gate pad GP. External connecting members are connected to the source pad SP and the gate pad GP, so that the semiconductor device 100 is electrically connected to another semiconductor chip, a lead frame, a wiring substrate, or the like. The external connecting member is, for example, a wire made of aluminum, gold, or copper, or a clip made of a copper plate.

As shown in FIG. 3, a plurality of trenches TR1 are formed in the semiconductor substrate SUB of the cell region CR. The plurality of trenches TR1 are formed in a stripe-like shape, extend in the Y direction, and adjoin each other in the X direction.

As shown in FIG. 4, inside the trench TR1, a field plate electrode FP is formed at a lower part of the trench TR1, and a gate electrode GE is formed at an upper part of the trench TR1. The field plate electrode FP and the gate electrode GE extend in the Y-direction along the trench TR1.

In addition, a part of the field plate FP forms a lead-out portion FPa. The field plate electrode FP constituting the lead-out portion FPa is formed not only in the lower part of the trench TR1 but also in the upper part of the trench TR1 inside the trench TR1.

As shown in FIG. 3, an outer peripheral trench TR2 is formed in the semiconductor substrate SUB of the outer peripheral region OR. In the X-direction, the plurality of trenches TR1 and the outer peripheral trench TR2 are arranged at the same pitch. In addition, the width of the outer peripheral trench TR2 is similar to that of the trench TR1. The outer peripheral trench TR2 extends in the Y direction and the X direction so as to surround the plurality of trenches TR1 in plan view. The outer peripheral trench TR2 has a corner part TR2c at a part where a part extending in the Y direction intersects with a part extending in the X direction. A field plate electrode FP (lead-out portion FPa) is formed inside the outer peripheral trench TR2.

Here, although two outer peripheral trenches TR2 are exemplified, the number of outer peripheral trenches TR2 may be one or three or more.

A hole CH3 is formed on each of the lead-out portions FPa of the cell region CR and the outer peripheral region OR. The lead-out portion FPa is electrically connected to the source electrode SE via the hole CH3. In the outer peripheral region OR, a hole CH2 is formed on the gate electrode GE. The gate electrode GE is electrically connected to the gate wiring GW via the hole CH2.

A cross-sectional configuration of the semiconductor device 100 will be described below with reference to FIG. 4.

Note that the cross-sectional view along C-C line shown in FIGS. 2 and 3 is substantially the same as the cross-sectional view along B-B line except that the reference numeral TR2 of the trench differs. Therefore, in the following, the description of the cross-sectional view along B-B line includes the description of the cross-sectional view along C-C line.

As shown in FIG. 4, the semiconductor device 100 comprises an n-type semiconductor substrate SUB having an upper surface TS and a lower surface BS. The semiconductor substrate SUB is made of silicon. The semiconductor substrate SUB has a low n-type concentration n-type drift region NV. In the first embodiment, the n-type semiconductor substrate SUB itself constitutes the drift region NV. The semiconductor substrate SUB may be a stack of an n-type silicon substrate and an n-type semiconductor layer grown on the n-type silicon substrate while introducing phosphorus (P) by an epitaxial growth method. In that case, the low-concentration n-type semiconductor layer constitutes the drift region NV, and the high-concentration n-type silicon substrate constitutes the drain region ND.

An n-type drain-region ND is formed at a lower part of the semiconductor substrate SUB. The drain region ND has a higher impurity concentration than the drift region NV. A drain-electrode DE is formed on the lower surface BS of the semiconductor substrate SUB. The drain electrode DE consists of a single layer of a metallic membrane, such as an aluminum membrane, a titanium membrane, a nickel membrane, a gold membrane or a silver membrane, or laminated membranes with these metallic membranes laminated accordingly. The drain region ND and the drain electrode DE are formed over the cell region CR and the outer peripheral region OR. The drain potential is supplied to the semiconductor substrate SUB (drain region ND, drift region NV) from the drain electrode DE.

In the semiconductor substrate SUB, a plurality of trenches TR1 are formed which reach a predetermined depth from the upper surface TS of the semiconductor substrate SUB toward the lower surface BS of the semiconductor substrate SUB. The depth of each trench TR1 is, for example, 5 μm (5 micrometers) or more and 10 μm (10 micrometers) or less. Inside the trench TR1, a field plate electrode FP is formed at a lower part of the trench TR1 via an insulating film IF1. Further, inside the trench TR1, a gate electrode GE is formed above the field plate electrode FP via a gate insulating film GI. Each of the field plate electrode FP and the gate electrode GE is formed of, for example, an n-type doped polycrystalline silicon film.

The position of the upper surface of the insulating film IF1 is lower than the position of the upper surface of the field plate electrode FP. The gate insulating film GI is formed inside the trench TR1 on the insulating film IF1. An insulating film IF2 is formed so as to cover the field plate electrode FP exposed from the insulating film IF1. The gate electrode GE is also formed between the field plate electrode FP exposed from the insulating film IF1 and the semiconductor substrate SUB via the gate insulating film GI and the insulating film IF2.

The insulating film IF1 is formed between the semiconductor substrate SUB and the field plate electrode FP. The insulating film IF2 is formed between the gate electrode GE and the field plate electrode FP. The gate insulating film GI is formed between the semiconductor substrate SUB and the gate electrode GE. The semiconductor substrate SUB, the gate electrode GE, and the field plate electrode FP are electrically insulated from each other by these insulating films.

The insulating film IF1, the insulating film IF2, and the gate insulating film GI are made of, for example, a silicon-oxide film. The thickness of the insulating film IF1 is larger than the thickness of each of the insulating films 2 and the gate insulating film GI. Inside the trench TR1, the thickness of the insulating film IF1 is, for example, 400 nm or more and 600 nm or less. In the trench TR1, the thicknesses of the insulating films IF2 and the gate insulating film GI are, for example, 50 nm or more and 100 nm or less, respectively. These thicknesses are thicknesses in the X direction.

A p-type body region PB that reaches a predetermined depth from the upper surface TS of the semiconductor substrate SUB toward the lower surface BS of the semiconductor substrate SUB is formed in the semiconductor substrate SUB. The depth of the body region PB from the upper surface TS of the semiconductor substrate SUB is shallower than the depth of the trench TR1 from the upper surface TS of the semiconductor substrate SUB. In the body region PB, an n-type source region NS is formed. The source region NS has a higher impurity concentration than the drift region NV.

An interlayer insulating film IL is formed on the upper surface TS of the semiconductor substrate SUB so as to cover the trench TR1. The interlayer insulating film IL is formed of, for example, a silicon oxide film. The thickness of the interlayer insulating film IL is, for example, 700 nm or more and 900 nm or less.

A hole CH1 is formed in the interlayer insulating film IL. The hole CH1 extends through the interlayer insulating film IL and the source region NS and reaches the body region PB. At the bottom of the hole CH1, a high-concentration diffusion region PR is formed in the body region PB. The high-concentration diffusion region PR has a higher impurity concentration than the body region PB. The high-concentration diffusion region PR is mainly provided to reduce the contact-resistance with the source electrode SE and to prevent latch-up.

A source electrode SE is formed on the interlayer insulating film IL. The source electrode SE is electrically connected to the source region NS, the body region PB, and the high-concentration diffusion region PR via the hole CH1 and supplies a source potential to these impurity regions.

As shown in B-B cross-section of FIG. 4, a part of the field plate electrode FP forms a lead-out portion FPa of the field plate electrode FP. The position of the upper surface of the insulating film IF1 in contact with the lead-out portion FPa is higher than the position of the upper surface of the insulating film IF1 in contact with the field plate electrode FP other than the lead-out portion FPa. An insulating film IF2 is formed on a side surface of the lead-out portion FPa. Further, a body region PB is formed in the semiconductor substrate SUB in contact with the trench TR1 in which the lead-out portion FPa is formed, but the source region NS is not formed in this body region PB.

As shown in B-B cross section of FIG. 4, the interlayer insulating film IL has a hole CH3 that extends through the interlayer insulating film IL and reaches the lead-out portion FPa. The source electrode SE is electrically connected to the lead-out portion FPa via the hole CH3, and supplies a source potential to the field plate electrode FP.

Although not illustrated here, the interlayer insulating film IL has a hole CH2 that extends through the interlayer insulating film IL and reaches the gate electrode GE. The gate wiring GW is electrically connected to the gate electrode GE via the hole CH2 and supplies a gate potential to the gate electrode GE.

The source electrode SE is also embedded in the hole CH1 and the hole CH3. The gate wiring GW is also embedded in the hole CH2. The source electrode SE and the gate wiring GW are made of, for example, a barrier metal film and a conductive film formed on the barrier metal film. The barrier metal film is, for example, a titanium tungsten film, and the conductive film is, for example, an aluminum alloy film to which copper or silicon is added.

The source electrode SE and the gate wiring GW may be formed by a plug layer that fills the insides of the holes CH1, CH2, CH3 and a wiring layer formed on the interlayer insulating film IL. In that case, the wiring layer is formed by the barrier metal film and the conductive film. The plug layer is formed by, for example, a stacked film of a barrier metal film such as a titanium nitride film and a conductive film such as a tungsten film.

### Main Features of First Embodiment

FIG. 5 is a main part plan view showing the periphery of the corner part TR2c of the outer peripheral trench TR2. FIG. 6 shows a depletion layer extending around the corner part TR2c.

As shown in FIG. 5, the outer peripheral trench TR2 has an extending part TR2a extending in the Y direction, an extending part TR2b extending in the X direction, and a corner part TR2c connecting the extending part TR2a and the extending part TR2b to each other. The corner part TR2c extends in a direction different from the Y and X directions in plan view, and extends in a direction inclined at an angle of 45 degrees from the Y and X directions, for example.

When such a corner part TR2c is not provided, the extending part TR2a and the extending part TR2b are connected at right angles. In this case, variations in the thickness of the insulating film IF1 tend to occur at the right-angled part, and a defect in embedding of the field plate electrode FP tends to occur. Further, since the distance from the right-angled part to the trench TR1 is long, it is difficult for the depletion layer extending from the right-angled part to reach the depletion layer from the trench TR1 closest to the extending part TR2a. A part where the depletion layer does not spread in this way causes a partial breakdown voltage drop. Therefore, in order to prevent these defects from occurring, it is preferable that a corner part TR2c is provided in the outer peripheral trench TR2.

In the following description, when describing the periphery of the corner part TR2c as shown in FIGS. 5 and 6, the trench TR1 closest to the extending part TR2a in the X direction is referred to as “nearest trench TR1”, and trenches TR1 other than the nearest trench TR1 are referred to as “other trenches TR1”. Here, as one of other trenches TR1, a trench TR1 adjacent to the nearest trench TR1 in the X-direction at the opposite side of the extending part TR2a is exemplified. That is, as one of other trenches TR1, a trench TR1 which is the next closest to the extending part TR2a after the nearest trench TR1 in the X-direction is exemplified.

Further, when describing the depletion layer as shown in FIG. 6, the depletion layer extending from the field plate electrode FP inside the trench TR1 to the drift region NV may be referred to as a “depletion layer from the trench TR1”, and the depletion layer extending from the field plate electrode FP inside the outer peripheral trench TR2 to the drift region NV may be referred to as a “depletion layer from the outer peripheral trench TR2”.

As shown in FIG. 5, each of the plurality of trenches TR1 has an end part 10 located close to the extending part TR2b in the Y-direction. However, in the Y-direction, the position of the end part 10 of the nearest trench TR1 is retracted by a distance L1 from the positions of the end parts 10 of other trenches TR1. In other words, in the Y-direction, the distance L2 between the end part 10 of the nearest trench TR1 and the extending part TR2b is longer than the distance L3 between the end parts 10 of other trenches TR1 and the extending part TR2b. In other words, in the Y-direction, the end part 10 of the nearest trench TR1 is further away from the extending part TR2b than the end parts 10 of other trenches TR1.

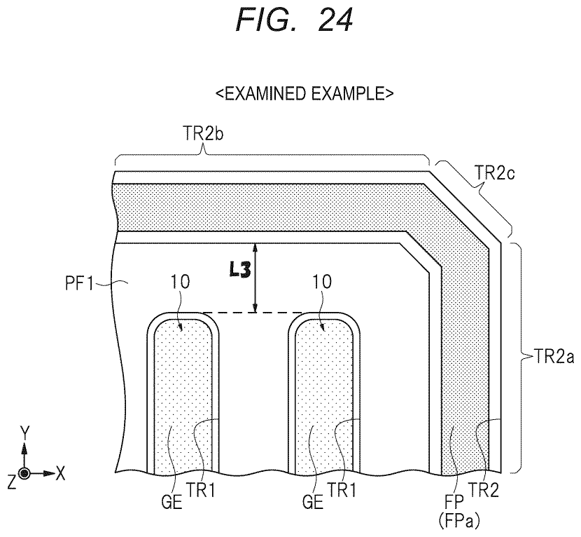

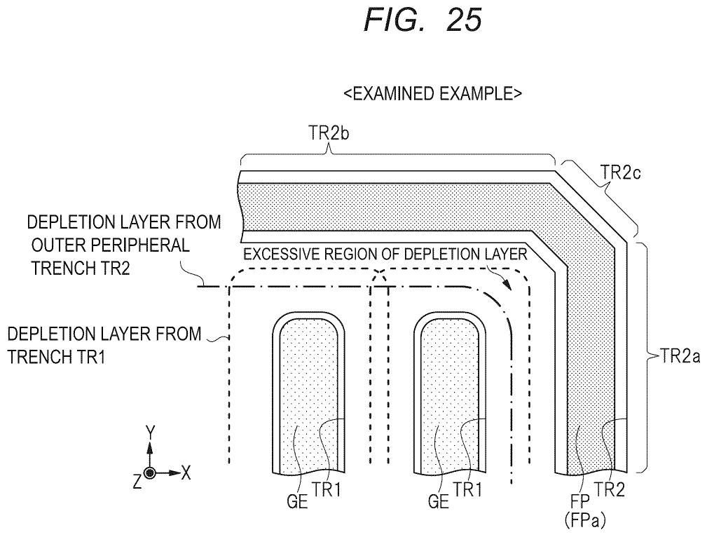

The reason for this will be described below with reference to an examined example. FIG. 24 and FIG. 25 show semiconductor device of an examined example studied by the present inventor.

As shown in FIG. 24, in the examined example, in the Y-direction, the distance L3 between the end part 10 of the nearest trench TR1 and the extending part TR2b is the same as the distance L3 between the end parts 10 of other trenches TR1 and the extending part TR2b. At this time, as shown in FIG. 25, the depletion layer spreads from the trench TR1 and the peripheral trench TR2, respectively, but there is an “excessive region” in which the depletion layer from the corner part TR2c and its outer peripheral and the depletion layer from the nearest trench TR1 overlap in a wide area.

Here, in a MOSFET of the split-gate structure, it is known that impact ionization occurs near the bottom of each of the trench TR1 and the outer peripheral trench TR2 at the time of avalanche breakdown, and hot holes generated at that time are implanted into the insulating film IF1. When the avalanche breakdown is repeated and such hot hole injections are accumulated in the insulating film IF1, the charge balance of the cell regions changes and the breakdown voltage becomes unstable.

A part where the depletion layer does not reach is a cause of a partial breakdown voltage drop. In order to prevent such a part from being generated, it is preferable that the depletion layer from the trench TR1 and the depletion layer from the outer peripheral trench TR2 overlap to some extent. However, in the “excessive region” as shown in FIG. 25, impact ionization tends to occur from a low electric field due to electric field concentration, and many hot holes are injected into the insulating film IF1.

In the first embodiment, the distance L2 is made longer than the distance L3, as shown in FIG. 5, in order to suppress the generation of such “excessive region”. As shown in FIG. 6, the overlap between the depletion layer from the corner part TR2c and the periphery thereof and the depletion layer from the nearest trench TR1 is reduced, so that impact ionization is relaxed and the quantity of hot holes injected into the insulating film IF1 can be suppressed. That is, according to the first embodiment, the breakdown voltage around the outer peripheral trench TR2 can be improved, and the breakdown voltage of the semiconductor device 100 can be stabilized.

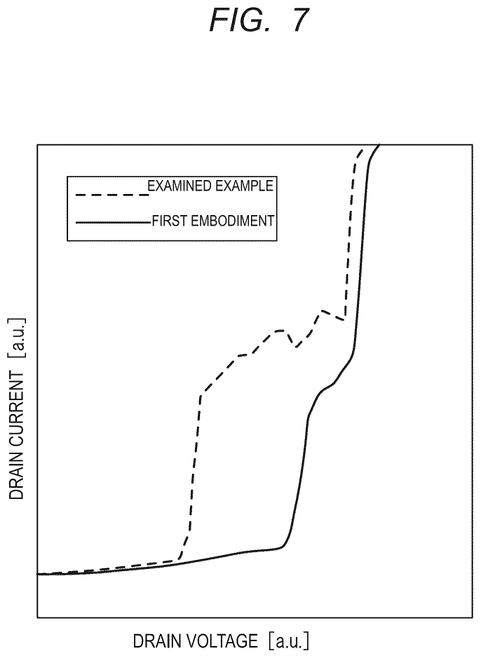

FIG. 7 is a graph showing a relationship between the drain current Id and the drain voltage Vd, and showing a result measured by the inventor of the present application after several breakdown operations are performed on the examined example and the first embodiment. As shown in FIG. 7, it can be seen that in the examined example, the drain current Id starts to flow when the drain voltage Vd is low. That is, in the examined example, it is found that a region with locally low voltage withstanding exists in the cell. On the other hand, it can be seen that such issue can be suppressed in the first embodiment.

### <Manufacturing Method of Semiconductor Device>

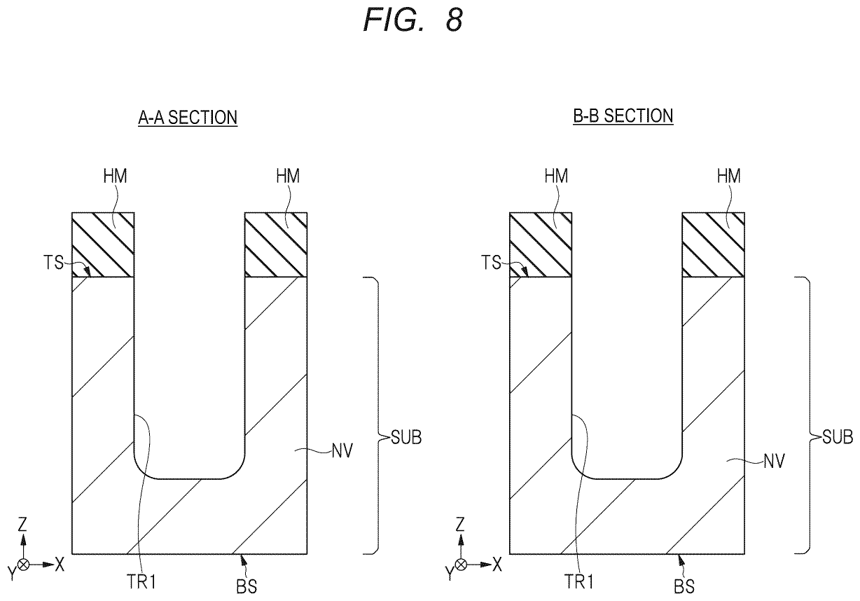

The respective manufacturing steps included in the manufacturing method of the semiconductor device 100 will be described below with reference to FIG. 8 to FIG. 16.

First, as shown in FIG. 8, an n-type semiconductor substrate SUB having an upper surface TS and a lower surface BS is prepared. As mentioned above, the semiconductor substrate SUB may be a stack of an n-type silicon substrate and an n-type semiconducting layer formed on the silicon substrate by epitaxial growth.

Next, a trench TR1 is formed in the semiconductor substrate SUB so as to reach a predetermined depth from the upper surface TS of the semiconductor substrate SUB toward the lower surface BS of the semiconductor substrate SUB. In order to form the trench TR1, for example, a silicon-oxide film is first formed on the semiconductor substrate SUB by, for example, CVD (Chemical Vapor Deposition). Next, the silicon oxide film is patterned by a photolithography technique and an anisotropic etch process to form a hard mask HM. Next, an anisotropic etch process is performed using the hard mask HM as a mask to form a trench TR1 in the semiconductor substrate SUB. Thereafter, the hard mask HM is removed by, for example, a wet etching process using a hydrofluoric acid-containing solution.

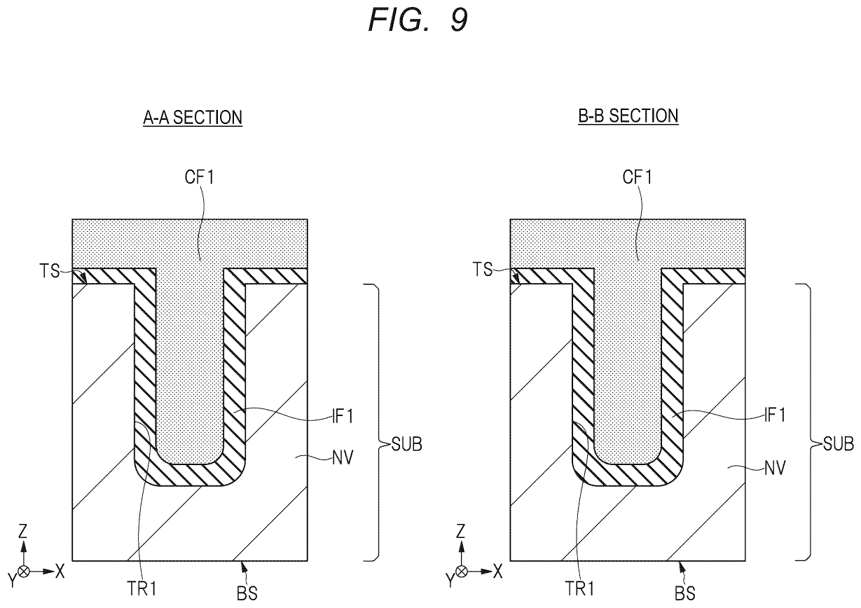

Next, as shown in FIG. 9, an insulating film IF1 is formed inside the trench TR1 and on the upper surface TS of the semiconductor substrate SUB. The insulating film IF1 is, for example, a silicon-oxide film formed by thermal oxidation treatment. The insulating film IF1 may be a stacked film of a first silicon oxide film formed by thermal oxidation treatment and a second silicon oxide film formed by CVD on the first silicon oxide film.

Next, a conductive film CF1 is formed on the insulating film IF1 by, e.g., CVD so as to fill the inside of the trench TR1. The conductive film CF1 is, for example, an n-type polycrystalline silicon film. In order to satisfactorily fill the inside of the trench TR1 with the conductive film CF1, the conductive film CF1 may be formed a plurality of times (for example, two times of forming including forming of the first polycrystalline silicon film and forming of the second polycrystalline silicon film).

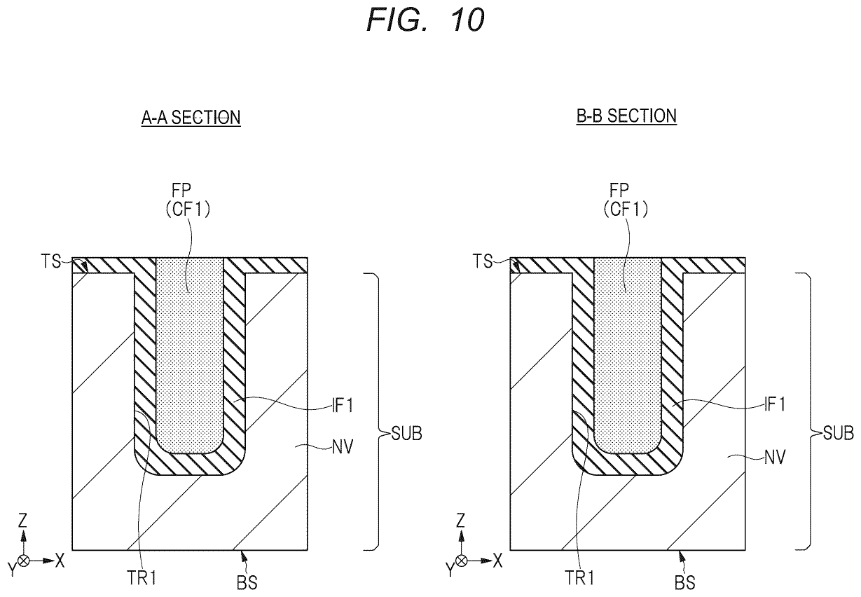

Next, as shown in FIG. 10, the conductive film CF1 located outside the trench TR1 is removed by a polishing process using, for example, CMP (Chemical Mechanical Polishing). As a result, the conductive film CF1 left in the trench TR1 is formed as the field plate electrode FP.

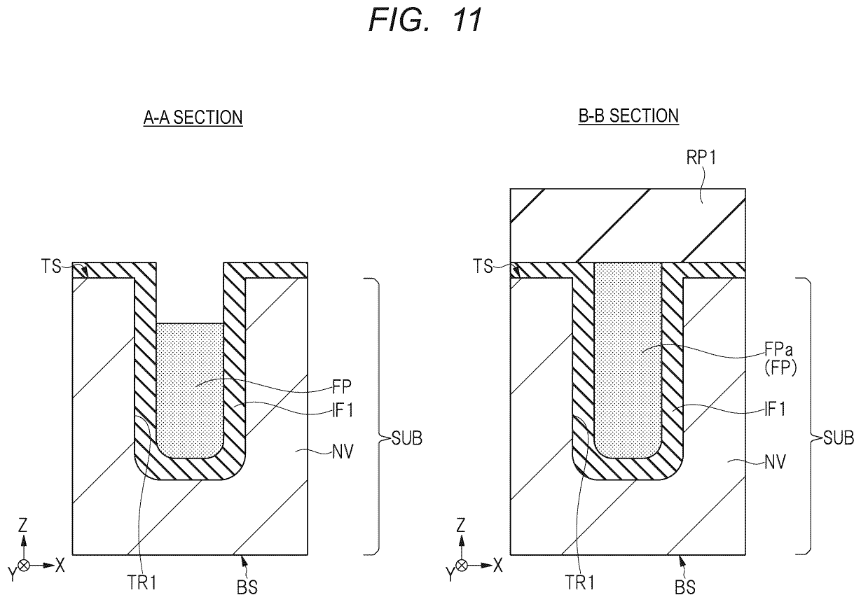

Next, as shown in FIG. 11, other parts of the field plate electrode FP are selectively removed so that a part of the field plate electrode FP is left as the lead-out portion FPa.

Specifically, first, as shown in B-B cross-section, a resist pattern RP1 that selectively covers a part of the field plate electrode FP which becomes the lead-out portion FPa is formed. Next, an etch process using, for example, an SF6 gas is performed using the resist pattern RP1 as a mask to remove a part of the field plate electrode FP that does not become the lead-out portion FPa. That is, as shown in A-A cross section, the other part of the field plate electrode FP that does not become the lead-out portion FPa is selectively retracted toward the bottom part of the trench TR1. A part of the field plate electrode FP that has not been retracted becomes the lead-out portion FPa. Thereafter, the resist pattern RP1 is removed by an ashing process.

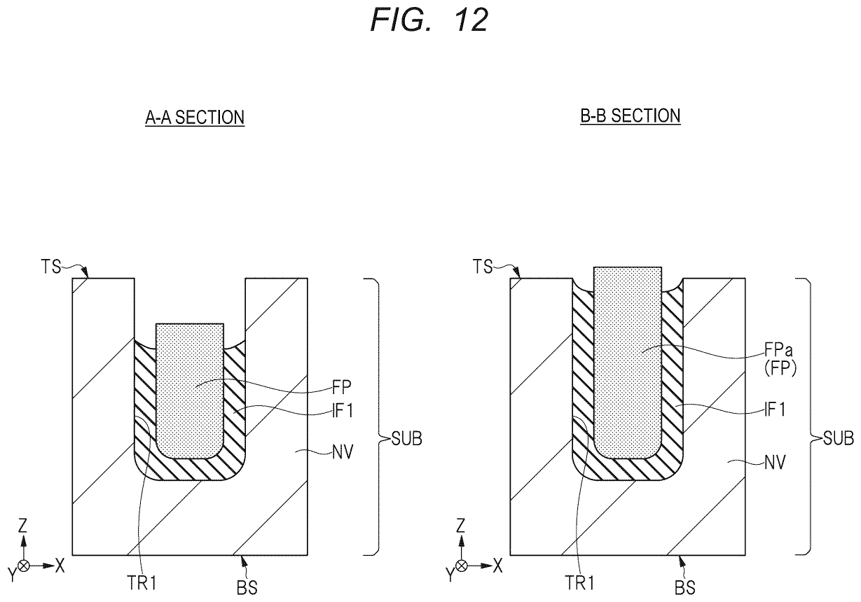

Next, as shown in FIG. 12, the insulating film IF1 is subjected to an isotropic etch process using solutions containing hydrofluoric acid. Accordingly, the insulating film IF1 located on the upper surface TS of the semiconductor substrate SUB is removed and the insulating film IF1 located inside the trench TR1 is retracted toward the bottom of the trench TR1 so that the position of the upper surface of the insulating film IF1 located inside the trench TR1 in the cross-sectional view is lower than the position of the upper surface of the field plate electrode FP.

At this point, the position of the upper surface of the insulating film IF1 in contact with the field plate electrode FP other than the lead-out portion FPa is lower than the position of the upper surface of the insulating film IF1 in contact with the lead-out portion FPa. Further, as shown in B-B cross section, the position of the upper surface of the lead-out portion FPa is higher than the position of the upper surface TS of the semiconductor substrate SUB since the insulating film IF1 on the upper surface TS of the semiconductor substrate SUB is removed.

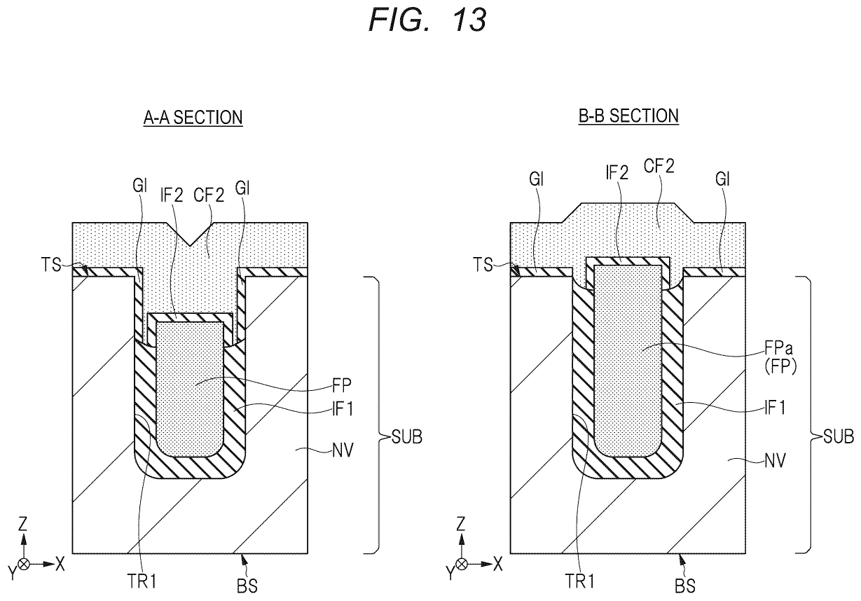

Next, as shown in FIG. 13, by performing the thermal oxidation treatment, a gate insulating film GI is formed inside the trench TR1 located on the insulating film IF1 and an insulating film IF2 is formed so as to cover the field plate electrode FP exposed from the insulating film IF1.

Next, a conductive film CF2 is formed on the gate insulating film GI and on the insulating film IF2 by, for example, a CVD method so as to fill the inside of the trench TR1. The conductive film CF2 is, for example, an n-type polycrystalline silicon film.

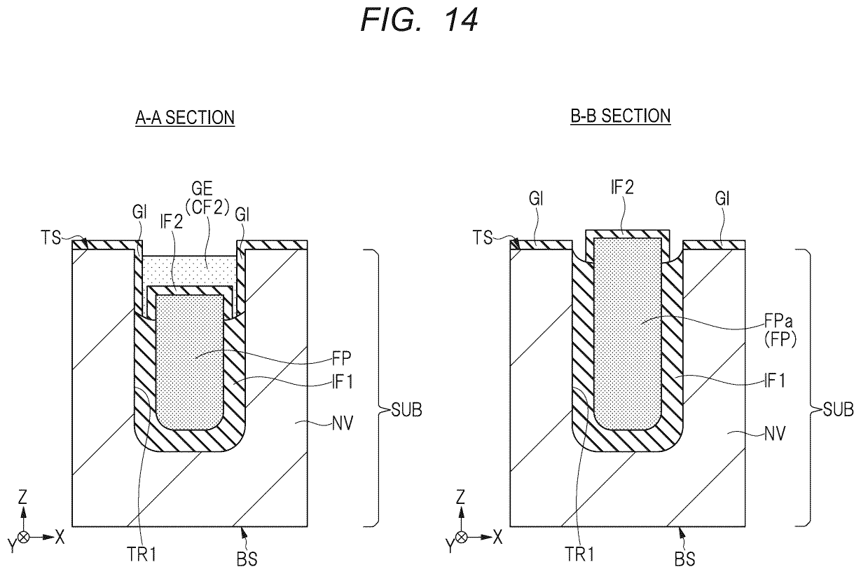

Next, as shown in FIG. 14, the conductive film CF2 is subjected to a polishing treatment using a CMP method. As a result, the thickness of the conductive film CF2 is reduced, and the upper surface of the conductive film CF2 is planarized. Next, an anisotropic etch process is performed on the conductive film CF2 to remove the conductive film CF2 located outside the trench TR1. Accordingly, the conductive film CF2 left in the trench TR1 is formed as the gate electrode GE on the field plate electrode FP.

In order to completely remove the conductive film CF2 outside the trench TR1, the anisotropic etching process is performed by over-etching. Therefore, as shown in A-A cross section, the position of the upper surface of the gate electrode GE is slightly lower than the position of the upper surface TS of the semiconductor substrate SUB. In addition, the conductive film CF2 formed on the insulating film IF2 in contact with the lead-out portion FPa is removed by the anisotropic etch process.

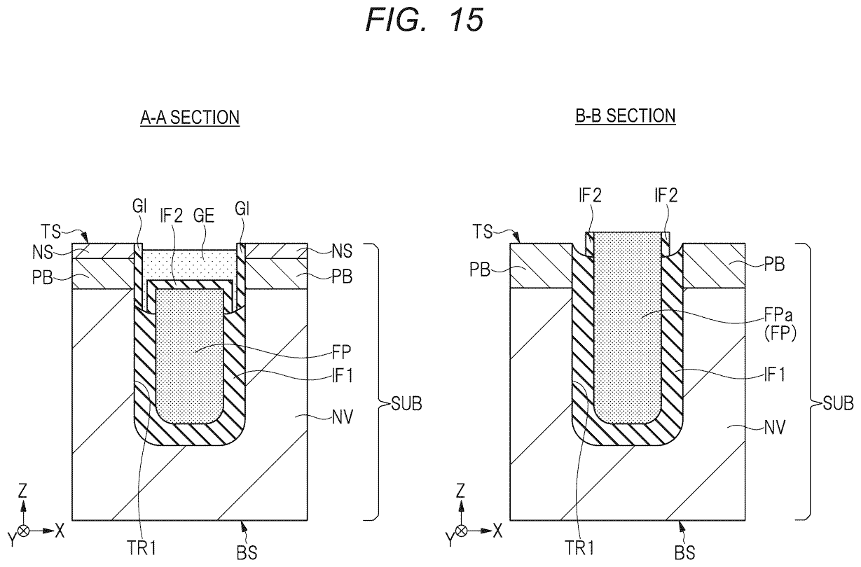

Next, as shown in FIG. 15, a p-type body region PB is selectively formed on the semiconductor substrate SUB of the cell region CR by introducing, for example, boron (B) by photolithography and ion-implantation.

Next, an n-type source region NS is selectively formed in the body region PB of the cell region CR by introducing, for example, arsenic (As) by photolithography and ion-implantation. Note that the source region NS is not formed in the body region PB adjoining the lead-out portion FPa. Thereafter, the semiconductor substrate SUB is subjected to a heat treatment to diffuse impurities contained in the source region NS and the body region PB.

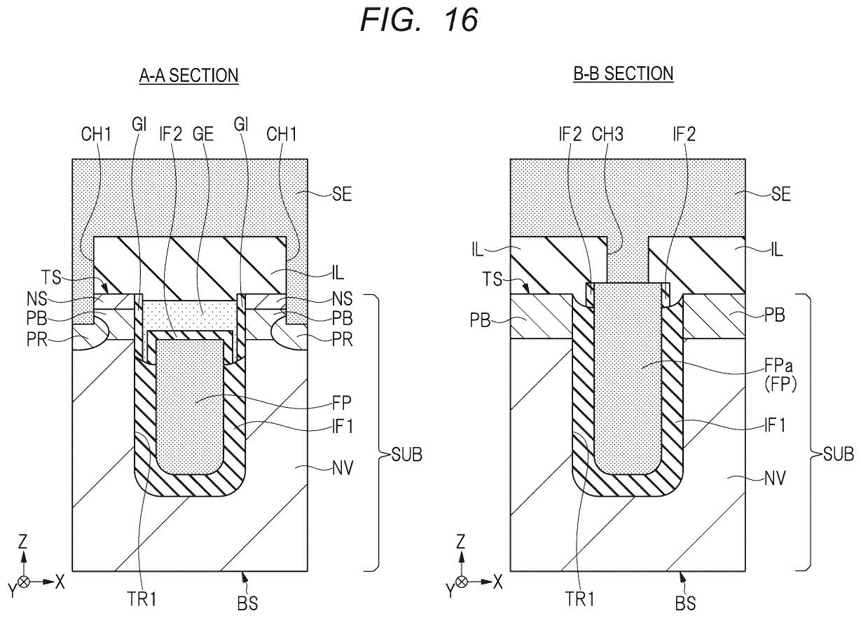

Next, as shown in FIG. 16, first, the interlayer insulating film IL is formed on the upper surface TS of the semiconductor substrate SUB by, for example, a CVD method so as to cover the trench TR1.

Next, holes CH1, CH2, and CH3 are formed in the interlayer insulating film IL. First, on the interlayer insulating film IL, a resist pattern having a pattern for opening the semiconductor substrate SUB in which the source region NS is formed is formed. Next, an anisotropic etch process is performed using the resist pattern as a mask to form a hole CH1 extending through the interlayer insulating film IL and the source region NS and reaching the inside of the body region PB. Next, a p-type high-concentration diffusion region PR is formed by introducing, for example, boron (B) into the body region PB at the bottom of the hole CH1 by the ion-implantation method. Thereafter, the resist pattern is removed by an ashing process.

Next, on the interlayer insulating film IL, a resist pattern having a pattern opening on the lead-out portion FPa and on the gate electrode GE is formed. Next, an anisotropic etch process is performed using the resist pattern as a mask to form a hole CH3 that extends through the interlayer insulating film IL and reaches the lead-out portion FPa. Although not illustrated here, in the step of forming the hole CH3, a hole CH2 that extends through the interlayer insulating film IL and reaches the gate electrode GE is also formed. Thereafter, the resist pattern is removed by an ashing process.

Note that any of the formation of the hole CH1 and the formation of the hole CH2 and the hole CH3 may be performed first.

Next, a source electrode SE is formed on the interlayer insulating film IL so as to fill the insides of the holes CH1, CH3, and a gate wiring GW is formed on the interlayer insulating film IL so as to fill the inside of the hole CH2.

Specifically, first, a first barrier metal film is formed inside the holes CH1, CH2, CH3 and on the interlayer insulating film IL by a sputtering method. The first barrier metal film is formed of, for example, a titanium tungsten film. Next, a first conductive film is formed on the first barrier metal film by sputtering. The first conductive film is, for example, an aluminum alloy film to which copper or silicon is added. Next, the source electrode SE and the gate wiring GW are formed by patterning the first barrier metal film and the first conductive film.

Next, although not illustrated here, a protective film made of, for example, a polyimide film is formed on the source electrode SE and the gate wiring GW by, for example, a coating method. By forming openings in parts of the protective film, regions of the source electrode SE and the gate wiring GW that become the source pad SP and the gate pad GP are exposed.

Thereafter, the structure shown in FIG. 4 is obtained through the following manufacturing process. First, the lower surface BS of the semiconductor substrate SUB is polished as needed. Next, an n-type drain region ND is formed by introducing, for example, arsenic (As) or the like into the lower surface BS of the semiconductor substrate SUB by ion-implantation. When the semiconductor substrate SUB is composed of a stack of an n-type silicon substrate and an n-type semiconductor layer, the high-concentration n-type silicon substrate forms a drain region ND, and thus forming of the drain region ND by the ion-implantation described above can be omitted. Next, a drain electrode DE is formed on the lower surface BS of the semiconductor substrate SUB by a sputtering method.

### Second Embodiment

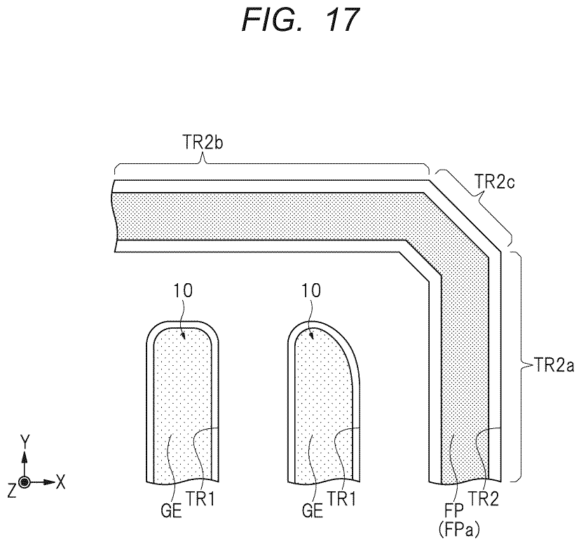

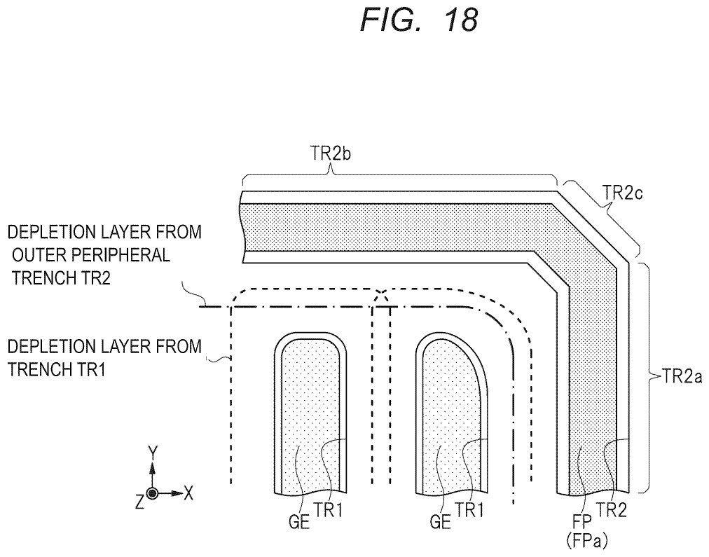

A semiconductor device 100 in the second embodiment will be described below with reference to FIG. 17 and FIG. 18. Note that, in the following description, differences from the first embodiment will be mainly described, and the description of overlapping points with the first embodiment will be omitted.

In the first embodiment, in order to suppress the generation of the “excessive region” shown in FIG. 25, the end part 10 of the nearest trench TR1 is moved away from the extending part TR2b in the Y-direction than the end parts 10 of other trenches TR1.

In the second embodiment, as shown in FIG. 17, the shape of the end part 10 of the nearest trench TR1 is different from the shapes of the end parts 10 of other trenches TR1. For example, the shape of the end part 10 of the nearest trench TR1 is recessed away from the corner part TR2c. In other words, the width of the end part 10 of the nearest trench TR1 in the X direction is narrower than the width of the nearest trench TR1 other than the end part 10 in the X direction and is continuously becoming narrower toward the extending part TR2b.

In order to change such the shape of the end part 10 of the nearest trench TR1, the pattern of the hard mask HM shown in FIG. 8 can be changed.

In the second embodiment as well as the first embodiment, generation of an “excessive region” can be suppressed, and the breakdown voltage around the outer peripheral trench TR2 can be improved. Therefore, the breakdown voltage of the semiconductor device 100 can be stabilized.

In addition, when comparing FIG. 18 of the second embodiment with FIG. 6 of the first embodiment, the second embodiment has higher uniformity of the overlap of the depletion layers extending from the respective trenches TR1, TR2. Therefore, in the second embodiment, the breakdown voltage around the peripheral trench TR2 is more easily stabilized than in the first embodiment.

On the other hand, if the end part 10 of the nearest trench TR1 is too thin, it is difficult to satisfactorily embed the insulating film IF1 and the field plate electrode FP in the end part 10. Therefore, the first embodiment is superior to the second embodiment in terms of the embeddability of the insulating film IF1 and the field plate electrode FP.

### Third Embodiment

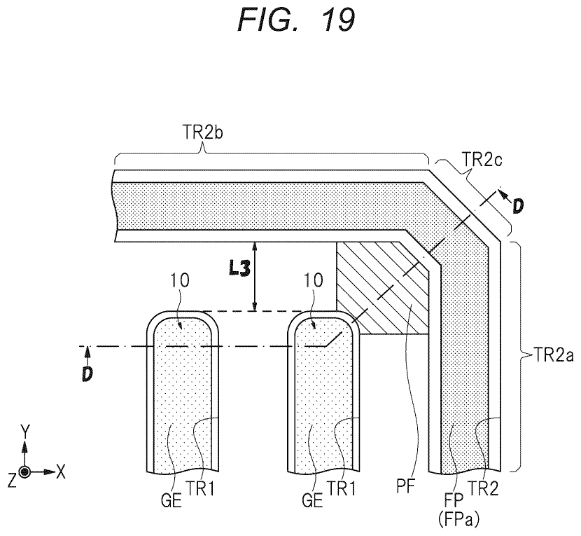

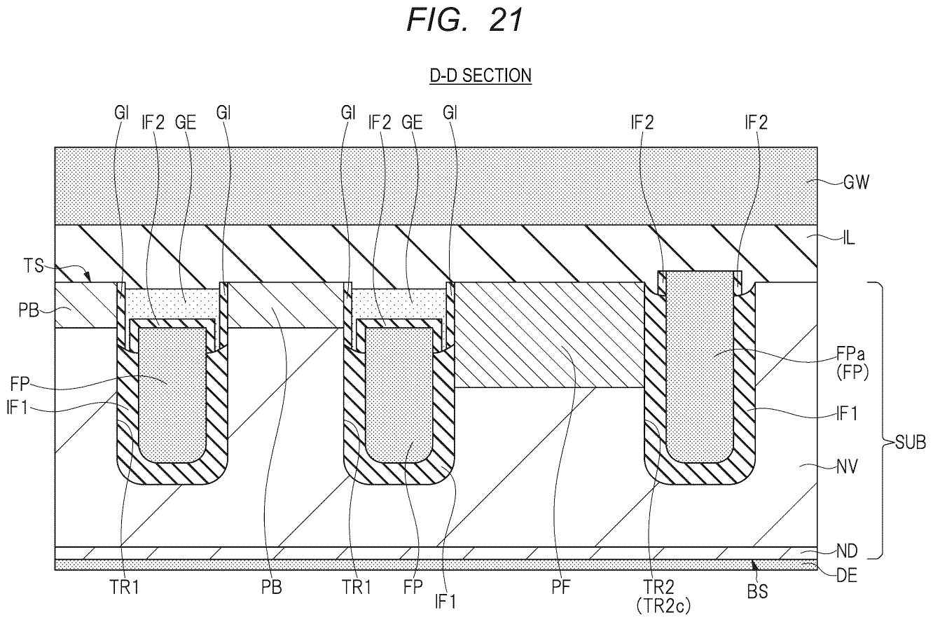

The semiconductor device 100 in the third embodiment will be described below with reference to FIG. 19 to FIG. 21. Note that, in the following description, differences from the first embodiment will be mainly described, and the description of overlapping points with the first embodiment will be omitted. FIG. 21 is a cross-sectional view along D-D line of FIG. 19.

In the third embodiment, as shown in FIG. 19, the distance between the end part 10 of the nearest trench TR1 and the extending part TR2b and the distance between the end part 10 of another trench TR1 and the extending part TR2b are the same distance L3. However, as shown in FIGS. 19 and 21, a floating region PF, which is a p-type impurity region, is formed in the semiconductor substrate SUB located between the corner part TR2c and the nearest trench TR1.

The impurity concentration of the floating region PF is higher than the impurity concentration of the p-type body region PB. In addition, the depth of the floating region PF from the upper surface TS of the semiconductor substrate SUB is deeper than the depth of the p-type body region PB from the upper surface TS of the semiconductor substrate SUB. The floating region PF is physically separated from the body region PB, is not electrically connected to the source electrode SE, and is electrically floating.

In order to form such a floating region PF, an additional ion-implantation step is performed. Before and after the manufacturing process of the body region PB of FIG. 15, an impurity such as boron (B) is selectively implanted into the semiconductor substrate SUB located between the corner part TR2c and the nearest trench TR1 using a photolithography technique and an ion implantation method. As a result, the floating region PF is formed.

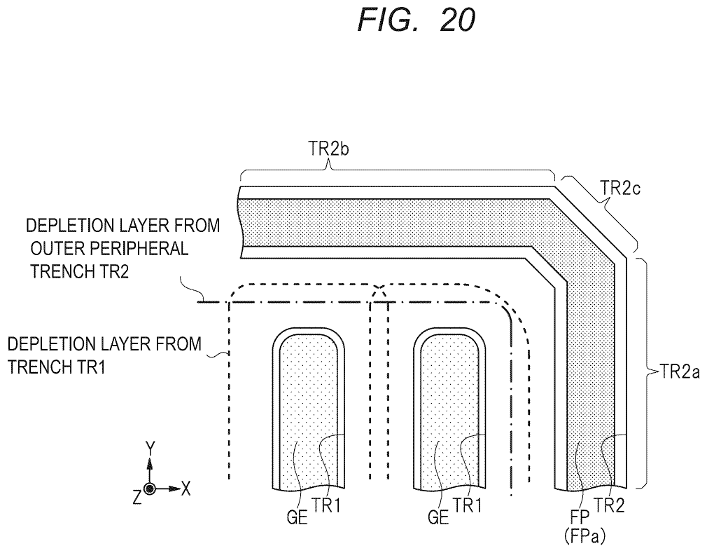

As shown in FIG. 20, by providing such a floating region PF, the spread of the depletion layer from the corner part TR2c and the periphery thereof and the spread of the depletion layer from the end part 10 of the nearest trench TR1 are suppressed. Therefore, in the third embodiment as well as the first embodiment, generation of the “excessive region” can be suppressed, and the breakdown voltage around the outer peripheral trench TR2 can be improved. Therefore, the breakdown voltage of the semiconductor device 100 can be stabilized.

### Fourth Embodiment

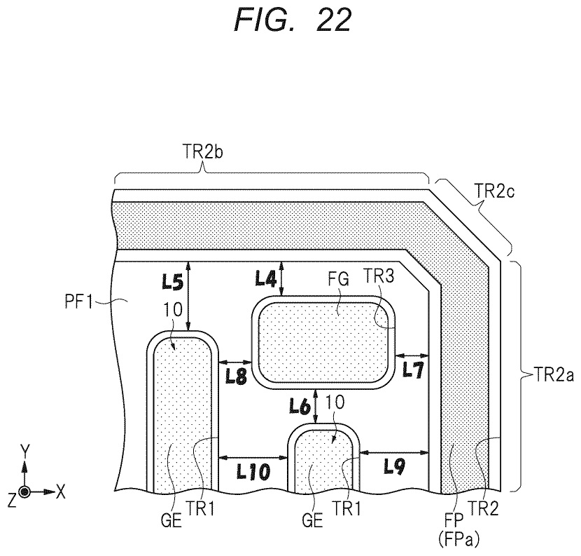

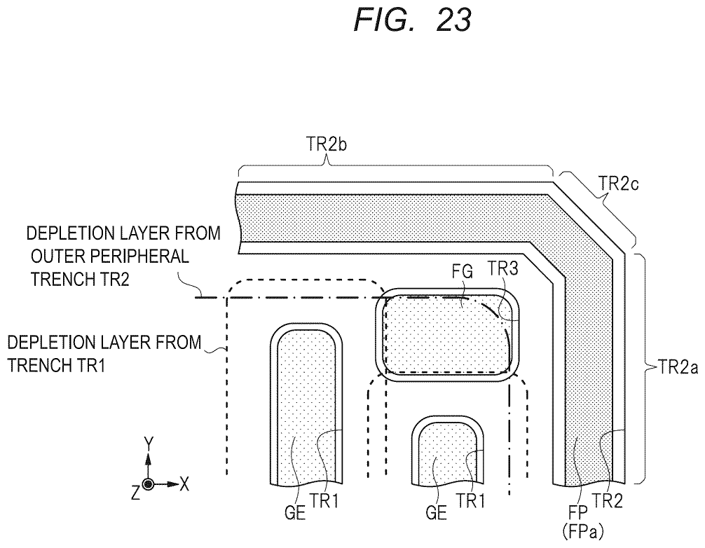

The semiconductor device 100 in the fourth embodiment will be described below with reference to FIG. 22 and FIG. 23. Note that, in the following description, differences from the first embodiment will be mainly described, and the description of overlapping points with the first embodiment will be omitted.

As shown in FIG. 22, the end part 10 of the nearest trench TR1 of the fourth embodiment is further away from the extending part TR2b than the end parts 10 of other trenches TR1. A trench TR3 is formed in the semiconductor substrate SUB located between the end part 10 of the nearest trench TR1 and the extending part TR2b so as to reach a predetermined depth from the upper surface TS of the semiconductor substrate SUB toward the lower surface BS of the semiconductor substrate SUB. The trench TR3 is formed during the manufacturing process of the trench TR1 and the outer peripheral trench TR2 but is not in communication with the trench TR1 and the peripheral trench TR2, and is formed as an independent trench.

A floating gate electrode FG is formed inside the trench TR3. The floating gate electrode FG is electrically isolated from the semiconductor substrate SUB and is electrically floating. The floating gate electrode FG is formed to relax an electric field around the corner part TR2c.

The internal structure of the trench TR3 may consist of an insulating film IF1, a gate insulating film GI, an insulating film IF2, a field plate electrode FP, and a gate electrode GE as the inside of the trench TR1 of the cell region CR. In that case, the field plate electrode FP and the gate electrode GE become the floating gate electrode FG, respectively, and there are two floating gate electrodes FG inside the trench TR3.

In addition, the internal structure of the trench TR3 may consist of the insulating film IF1 and the field plate electrode FP (the lead-out portion FPa) as well as the inside of the outer peripheral trench TR2 of the outer peripheral region OR. In that case, the field plate electrode FP (the lead-out portion FPa) becomes the floating gate electrode FG.

However, when the trench TR3 and the floating gate electrode FG are simply provided, there is a case in which there is a position which the depletion layer of any of the nearest trench TR1, other trenches TR1, or the outer peripheral trench TR2 does not reach.

Therefore, as shown in FIG. 23, it is preferable that the shape of the trench TR3 is adjusted so that all of the depletion layers from the nearest trench TR1, other trenches TR1, or the outer peripheral trench TR2 overlap the floating gate electrode FG in plan view. Accordingly, if necessary, the shape of the trench TR3 is adjusted so as to be similar to the nearest trench TR1, other trenches TR1, or the outer peripheral trench TR2.

For example, as shown in FIG. 22, in the Y-direction, the distance L4 between the trench TR3 and the extending part TR2b and the distance L6 between the trench TR3 and the end part 10 of the nearest trench TR1 are shorter than the distance L5 between the end part 10 of another trench TR1 and the extending part TR2b. Further, in the X-direction, the distance L7 between the trench TR3 and the extending part TR2a and the distance L8 between the trench TR3 and another trench TR1 are shorter than the distance L9 between the nearest trench TR1 and the extending part TR2a and the distance L10 between the nearest trench TR1 and another trench TR1.

In the fourth embodiment as well as the first embodiment, generation of an “excessive region” can be suppressed, and the breakdown voltage around the outer peripheral trench TR2 can be improved. Therefore, the breakdown voltage of the semiconductor device 100 can be stabilized.

Although the present invention has been described in detail based on the above-described embodiments, the present invention is not limited to the above-described embodiments and can be variously modified without departing from the gist thereof.

What is claimed is:

1. A semiconductor device comprising:
a semiconductor substrate of a first conductivity type having an upper surface and a lower surface;
a plurality of trenches being formed in the semiconductor substrate so as to reach a predetermined depth from the upper surface of the semiconductor substrate to the lower surface of the semiconductor substrate, the plurality of trenches extending in a first direction in plan view and adjacent to each other in a second direction orthogonal to the first direction in plan view;
a plurality of first field plate electrodes formed inside the plurality of trenches, respectively, and electrically insulated from the semiconductor substrate;
a plurality of first gate electrodes formed above the plurality of first field plate electrodes, respectively, and electrically insulated from the semiconductor substrate and the plurality of first field plate electrodes, respectively;
an outer peripheral trench formed in the semiconductor substrate so as to reach a predetermined depth from the upper surface of the semiconductor substrate toward the lower surface of the semiconductor substrate, the outer peripheral trench extending in the first direction and the second direction so as to surround the plurality of trenches in plan view; and
a second field plate electrode formed inside the outer peripheral trench and electrically insulated from the semiconductor substrate,
wherein the outer peripheral trench comprises:
a first extending part extending in the first direction;
a second extending part extending in the second direction; and
a corner part extending in a direction different from the first and second directions in plan view and interconnecting the first extending part and the second extending part,
wherein the plurality of trenches comprises:
a first trench closest to the first extending part in the second direction; and
a second trench next closest to the first extending part after the first trench in the second direction,
wherein the first trench has a first end part located near the second extending part in the first direction,
wherein the second trench has a second end part located near the second extending part in the first direction, and
wherein a distance between the first end part and the second extending part is longer than a distance between the second end part and the second extending part in the first direction.

2. The semiconductor device according to claim 1, wherein a gate potential is supplied to the plurality of first gate electrodes, and a source potential is supplied to the plurality of first field plate electrodes and the second field plate electrode.

3. The semiconductor device according to claim 1, wherein the corner part extends in a direction inclined at an angle of 45 degrees from the first direction and the second direction in plan view.

4. The semiconductor device according to claim 1,
wherein, in the semiconductor substrate located between the first end part and the second extending part, a third trench is formed so as to reach a predetermined depth from the upper surface of the semiconductor substrate toward the lower surface of the semiconductor substrate, and
wherein a floating gate electrode electrically isolated from the semiconductor substrate is formed inside the third trench.

5. The semiconductor device according to claim 4,
wherein, in the first direction, a distance between the third trench and the second extending part and a distance between the third trench and the first end part are shorter than the distance between the second end part and the second extending part, and
wherein, in the second direction, a distance between the third trench and the first extending part and a distance between the third trench and the second trench are shorter than a distance between the first trench and the first extending part and a distance between the first trench and the second trench.

6. The semiconductor device according to claim 4,
wherein a gate potential is supplied to the plurality of first gate electrodes,
wherein a source potential is supplied to the plurality of first field plate electrodes and the second field plate electrode, and
wherein the floating gate electrode is electrically floating.

7. The semiconductor device according to claim 4, wherein the corner part extends in a direction inclined at an angle of 45 degrees from the first direction and the second direction in plan view.

8. A semiconductor device comprising:
a semiconductor substrate of a first conductivity type having an upper surface and a lower surface;
a plurality of trenches being formed in the semiconductor substrate so as to reach a predetermined depth from the upper surface of the semiconductor substrate to the lower surface of the semiconductor substrate, the plurality of trenches extending in a first direction in plan view and adjacent to each other in a second direction orthogonal to the first direction in plan view;
a plurality of first field plate electrodes formed inside the plurality of trenches, respectively, and electrically insulated from the semiconductor substrate;
a plurality of first gate electrodes formed above the plurality of first field plate electrodes, respectively, and electrically insulated from the semiconductor substrate and the plurality of first field plate electrodes, respectively;
an outer peripheral trench formed in the semiconductor substrate so as to reach a predetermined depth from the upper surface of the semiconductor substrate toward the lower surface of the semiconductor substrate, the outer peripheral trench extending in the first direction and the second direction so as to surround the plurality of trenches in plan view; and
a second field plate electrode formed inside the outer peripheral trench and electrically insulated from the semiconductor substrate,
wherein the outer peripheral trench comprises:
a first extending part extending in the first direction;
a second extending part extending in the second direction; and
a corner part extending in a direction different from the first and second directions in plan view and interconnecting the first extending part and the second extending part,
wherein the plurality of trenches comprises:
a first trench closest to the first extending part in the second direction; and
a second trench next closest to the first extending part after the first trench in the second direction,
wherein the first trench has a first end part located near the second extending part in the first direction,
wherein the second trench has a second end part located near the second extending part in the first direction, and
wherein the shape of the first end part is different from the shape of the second end part.

9. The semiconductor device according to claim 8, wherein the first end part has a shape that is recessed toward a direction going away from the corner part.

10. The semiconductor device according to claim 8, wherein a width of the first end part in the second direction is narrower than a width of the first trench other than the first end part in the second direction and is continuously becoming narrower toward the second extending part.

11. The semiconductor device according to claim 8,
wherein a gate potential is supplied to the plurality of first gate electrodes, and
wherein a source potential is supplied to the plurality of first field plate electrodes and the second field plate electrode.

12. The semiconductor device according to claim 8, wherein the corner part extends in a direction inclined at an angle of 45 degrees from the first direction and the second direction in plan view.

13. A semiconductor device comprising:
a semiconductor substrate of a first conductivity type having an upper surface and a lower surface;
a plurality of trenches being formed in the semiconductor substrate so as to reach a predetermined depth from the upper surface of the semiconductor substrate to the lower surface of the semiconductor substrate, the plurality of trenches extending in a first direction in plan view and adjacent to each other in a second direction orthogonal to the first direction in plan view;
a plurality of first field plate electrodes formed inside the plurality of trenches, respectively, and electrically insulated from the semiconductor substrate;
a plurality of first gate electrodes formed above the plurality of first field plate electrodes, respectively, and electrically insulated from the semiconductor substrate and the plurality of first field plate electrodes, respectively;
an outer peripheral trench formed in the semiconductor substrate so as to reach a predetermined depth from the upper surface of the semiconductor substrate toward the lower surface of the semiconductor substrate, the outer peripheral trench extending in the first direction and the second direction so as to surround the plurality of trenches in plan view;
a second field plate electrode formed inside the outer peripheral trench and electrically insulated from the semiconductor substrate; and
a first impurity region formed in the semiconductor substrate located between the plurality of trenches and the outer peripheral trench and having a second conductivity type opposite to the first conductivity type,
wherein the outer peripheral trench comprises:
a first extending part extending in the first direction;
a second extending part extending in the second direction; and
a corner part extending in a direction different from the first and second directions in plan view and interconnecting the first extending part and the second extending part,
wherein the plurality of trenches comprises a first trench closest to the first extending part in the second direction,
wherein a second impurity region is formed in the semiconductor substrate located between the corner part and the first trench, and
wherein an impurity concentration of the second impurity region is higher than an impurity concentration of the first impurity region.

14. The semiconductor device according to claim 13, wherein a depth of the second impurity region from the upper surface of the semiconductor substrate is deeper than a depth of the first impurity region from the upper surface of the semiconductor substrate.

15. The semiconductor device of claim 13,
wherein the plurality of trenches further comprises a second trench next closest to the first extending part after the first trench in the second direction,
wherein the first trench comprises a first end part located in the vicinity of the second extending part in the first direction,
wherein the second trench comprises a second end part located in the vicinity of the second extending part in the first direction, and
wherein, in the first direction, a distance between the first end part and the second extending part is the same as a distance between the second end part and the second extending part.

16. The semiconductor device according to claim 13,
wherein a gate potential is supplied to the plurality of first gate electrodes,
wherein a source potential is supplied to the plurality of first field plate electrodes and the second field plate electrode, and
wherein the first impurity region and the second impurity region are electrically floating.

17. The semiconductor device according to claim 13, wherein the corner part extends in a direction inclined at an angle of 45 degrees from the first direction and the second direction in plan view.
